(19) United States
(12) Patent Application Publication
(10) Pub. No.: US 2013/0210174 A1
(43) Pub. Date: Aug. 15, 2013

(54) RESIN COATING DEVICE AND RESIN COATING METHOD

(71) Applicant: Masaru Nonomura, Osaka (JP)

(72) Inventor: Masaru Nonomura, Osaka (JP)

(73) Assignee: PANASONIC CORPORATION, Osaka (JP)

(21) Appl. No.: 13/881,881

(22) PCT Filed: May 11, 2011
(86) PCT No.: PCT/JP2011/002615

§ 371 Date: Apr. 26, 2013

(30) Foreign Application Priority Data
Oct. 27, 2010 (JP) 2010-240467

(51) Int. Cl. H01L 21/67

(52) U.S. Cl. CPC H01L 21/6715; H01L 22/10
USPC 438/15; 118/696

(57) ABSTRACT

In a resin coating used for manufacturing an LED package including an LED element coated with resin containing phosphor, a light-transmitting member test-coated with resin for an emission characteristic measurement on a light-transmitting member placing section including a light source unit, a deviation between a measurement result of an emission characteristic of light emitted from the resin coated on the light-transmitting member measured by an emission characteristic measurement unit by irradiating the resin with excitation light emitted from the light source unit and a prescribed emission characteristic is obtained, and an appropriate resin coating amount of the resin to be coated on the LED element for an actual production is derived based on the deviation.

### TECHNICAL FIELD

The present invention relates to a resin coating device and a resin coating method used in an LED package manufacturing system for manufacturing an LED package including an LED element mounted on a substrate and coated with resin containing phosphor.

### BACKGROUND ART

An LED (light-emitting diode) presents superior characteristics such as lower power consumption and longer lifetime is widely used as a light source for various illuminating devices. The fundamental light emitted from an LED element is currently limited to three: red, green and blue. In order to generate white light suitable for general illumination purposes, a method of generating white light by adding and mixing the three colors of the fundamental light or a method of generating pseudo white light by combination of a blue LED with a phosphor which emits yellow fluorescent light which is complementary to a blue color. In recent years, the latter method is more widely used. An illuminating device using an LED package including a combination of a blue LED and YAG phosphor is widely used, for example, for a backlight of a liquid-crystal panel (see, for example, Patent Document 1).

In the example of Patent Document, an LED element is mounted on a bottom of a recessed mounting portion including a reflection surface formed on a sidewall. Subsequently, a resin package portion is formed by pouring silicone resin, an epoxy resin, or the like, containing YAG-based phosphor particles dispersed therein into the mounting portion, whereby an LED package is produced. There are also described an example in which an excess resin storage portion storing excess resin poured in excess of a specified amount discharged from the resin mounting portion is formed for equalizing heights of the resin package portions formed in the mounting portions after pouring of resin. Even when a discharge rate of a dispenser varies at pouring of resin, the resin package portion having a given amount of resin and a defined height is formed on an LED element.

### RELATED ART DOCUMENTS

### Patent Documents

Patent Document 1: JP-A-2007-66969

### SUMMARY OF THE INVENTION

### Problem to be Solved by the Invention

However, the example of the related art has a problem variation of an emission characteristic of the LED package as a completed product caused by a variation in emission wavelength of individual LED elements. Specifically, the LED elements are manufactured through a process in which a plurality of elements are collectively formed on a wafer. Due to various error factors in the manufacturing process, for example, uneven composition occurring at formation of a film on the wafer, variations in emission wavelength inevitably cause in the LED elements separated as pieces from the wafer. In the example, the heights of the resin packages covering the LED elements are uniformly set. Therefore, variations in the emission wavelength of the LED elements are reflected as variations in emission characteristics of the respective LED packages as the completed products. As a result, the number of defective products which are out of an acceptable quality range increases. As described above, the related-art LED package manufacturing technique has a problem in which variations in emission wavelength of LED elements causes variations in emission characteristics of LED packages as products, which leads to deterioration of product yield.

An object of the present invention is to provide a resin coating device and a resin coating method capable of maintaining a uniform emission characteristic of LED packages even when emission wavelengths of pieces of LED elements vary, thereby improving product yield.

### Means for Solving the Problem

A resin coating device of the present invention is used in an LED package manufacturing system for manufacturing an LED package including an LED element mounted on a substrate and coated with resin containing phosphor, and coats the LED element mounted on the substrate with the resin. The resin coating device includes: a resin coating section which discharges the resin by variably adjusting an amount thereof and which coats an arbitrary coating target position with the resin; a coating control unit which controls the resin coating section to execute a measurement coating process in which a light-transmitting member is test-coated with the resin for measuring an emission characteristic and a production coating process in which the LED element is coated with the resin for an actual production; a light-transmitting member placing section which includes a light source unit which emits excitation light which excites the phosphor, and on which the light-transmitting member coated with the test-coated resin is to be placed in the measurement coating process; an emission characteristic measurement unit which measures an emission characteristic of light emitted from the resin coated on the light-transmitting member by irradiating the resin with the excitation light emitted from the light source unit; a coating amount derivation processing unit which obtains a deviation between a measurement result of the emission characteristic measurement unit and a prescribed emission characteristic, and which derives an appropriate resin coating amount of the resin to be coated on the LED element for the actual production based on the deviation; and a production execution processing unit which informs the coating control unit of the appropriate resin coating amount to execute the production coating process to coat the LED element with the appropriate resin coating amount of the resin.

A resin coating method of the present invention is used in an LED package manufacturing system for manufacturing an LED package including an LED element mounted on a substrate and coated with resin containing phosphor, and coats the LED element mounted on the substrate with the resin. The resin coating method includes: a measurement coating step of test-coating a light-transmitting member with the resin by a resin coating section which discharges the resin by variably adjusting an amount thereof; a light-transmitting member placing step of placing the light-transmitting member coated with the test-coated resin on a light-transmitting member placing section which includes a light source unit which emits excitation light which excites the phosphor; an emission characteristic measurement step of measuring an emission characteristic of light emitted from the resin coated on the light-transmitting member by irradiating the resin with the excitation light emitted from the light source unit; a coating amount derivation processing step of obtaining a deviation between a measurement result of the emission characteristic measurement unit and a prescribed emission characteristic, and deriving an appropriate resin coating amount of the resin to be coated on the LED element for an actual production based on the deviation; and a production execution step of executing a production coating process to coat the LED element with the appropriate resin coating amount of the resin by informing a coating control unit controlling the resin coating section of the appropriate resin coating amount.

### ADVANTAGES OF THE INVENTION

According to the present invention, it is possible to maintain a uniform emission characteristic of LED packages even when emission wavelengths of pieces of LED elements vary, thereby improving product yield.

### BRIEF DESCRIPTION OF THE DRAWINGS

FIG. 1 is a block diagram showing a configuration of an LED package manufacturing system according to an embodiment of the present invention.

FIGS. 2(a) and 2(b) are diagrams showing a configuration of an LED package manufactured by the LED package manufacturing system according to the embodiment of the present invention.

FIGS. 3(a), 3(b), 3(c), and 3(d) are diagrams showing form of supplying LED elements and element characteristic information on the LED elements used in the LED package manufacturing system according to the embodiment of the present invention.

FIG. 4 is a diagram showing resin coating information used in the LED package manufacturing system according to the embodiment of the present invention.

FIGS. 5(a), 5(b), and 5(c) are diagrams showing a configuration and function of a component mounting device in the LED package manufacturing system according to the embodiment of the present invention.

FIG. 6 is a diagram showing map data used in the LED package manufacturing system according to the embodiment of the present invention.

FIGS. 7(a) and 7(b) are diagrams showing a configuration and function of a resin coating device in the LED package manufacturing system according to the embodiment of the present invention.

FIGS. 8(a), 8(b) and 8(c) is a diagram showing a configuration of an emission characteristic inspection device provided in the resin coating device in the LED package manufacturing system according to the embodiment of the present invention.

FIG. 9 is a block diagram showing a configuration of a control system of the LED package manufacturing system according to the embodiment of the present invention.

FIG. 10 is a flowchart showing a manufacture of an LED package executed by the LED package manufacturing system according to the embodiment of the present invention.

FIG. 11 is a flowchart showing a process for creating non-defective product determining threshold value data in the LED package manufacturing system according to the embodiment of the present invention.

FIGS. 12(a), 12(b), and 12(c) are diagrams showing the non-defective product determining threshold value data in the LED package manufacturing system according to the embodiment of the present invention.

FIGS. 13 is a chromaticity diagram showing the non-defective product determining threshold value data in the LED package manufacturing system according to the embodiment of the present invention.

FIG. 14 is a flowchart showing a resin coating work process during a manufacture of the LED package in the LED package manufacturing system according to the embodiment of the present invention.

FIGS. 15(a), 15(b), 15(c), and 15(d) are diagrams showing the resin coating work process during the manufacture of the LED package in the LED package manufacturing system according to the present invention.

FIGS. 16(a), 16(b), 16(c), and 16(d) are descriptive process charts showing processes for manufacturing an LED package in the LED package manufacturing system of the embodiment of the present invention.

FIGS. 17(a), 17(b), 17(c), and 17(d) are descriptive process charts showing processes for manufacturing an LED package in the LED package manufacturing system of the embodiment of the present invention.

### MODE FOR CARRYING OUT THE INVENTION

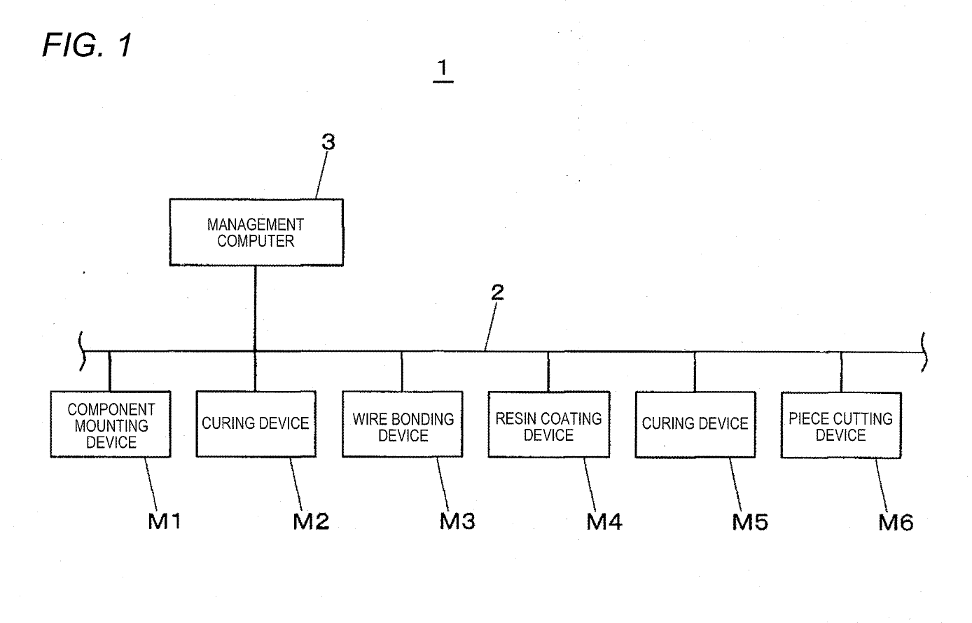

With reference to the drawings, an embodiment of the present invention will now be described. First, a configuration of an LED package manufacturing system 1 is described with reference to FIG. 1. The LED package manufacturing system 1 has a function of manufacturing an LED package in which an LED element mounted on a substrate is covered with resin containing phosphor. As shown in FIG. 1, in the present embodiment, the LED package manufacturing system includes a component mounting device M1, a curing device M2, a wire bonding device M3, a resin coating device M4, a curing device M5, and a piece cutting device M6, which are connected via a LAN system 2, and also includes a management computer 3 collectively controls the devices.

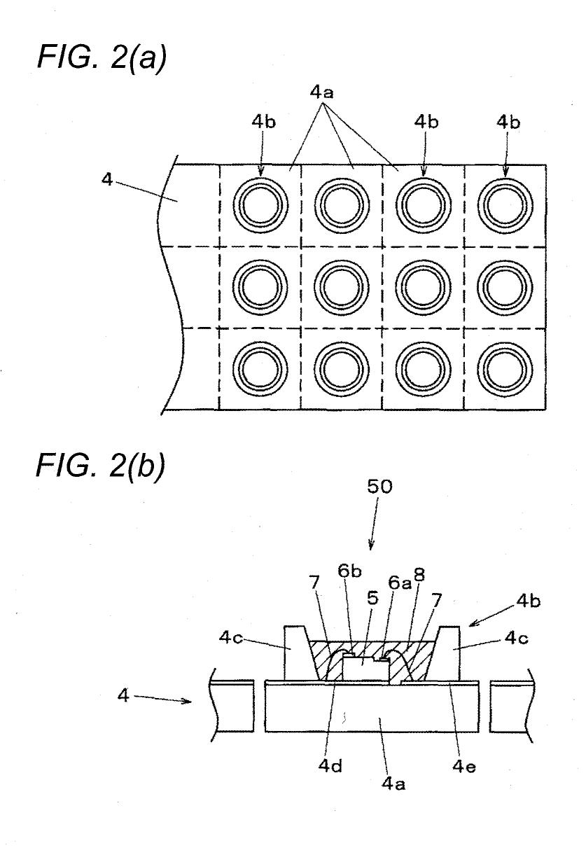

The component mounting device M1 bonds and mounts LED elements 5 on a substrate 4 (see FIG. 2) as a base of an LED package, with a resin adhesive. The curing device M2 heats the substrate 4 on which the LED elements 5 are mounted, thereby curing the resin adhesive used for bonding at mounting operation. The wire bonding device M3 connects electrodes of the substrate 4 to electrodes of the LED elements 5 by wire bonding. The resin coating device M4 coats the wire-bonded substrate 4 with the phosphor-containing resin for each of the LED elements 5. The curing device M5 heats the substrate 4 coated with the resin, thereby curing the coated resin so as to cover the LED elements 5. The piece cutting device M6 cuts the substrate 4 with cured resin into pieces of the LED elements 5, whereby the LED elements 5 are separated into respective LED packages. Accordingly, the LED packages divided into pieces are completed.

FIG. 1 shows an example of a production line configured by series-connecting the component mounting device M1 to the piece cutting device M6. However, it is not necessary to adopt such a line configuration for the LED package manufacturing system 1. So long as information described below is appropriately transferred, the devices may be provided in a distributed manner and sequentially execute work of respective steps. Further, a plasma processing device which performs plasma process for cleaning the electrodes prior to the wire-bonding may be disposed before or after the wire bonding device M3. Further, a plasma processing device which performs plasma process for surface modification to improve adhesion of resin prior to the resin coating after the wire-bonding may be disposed.

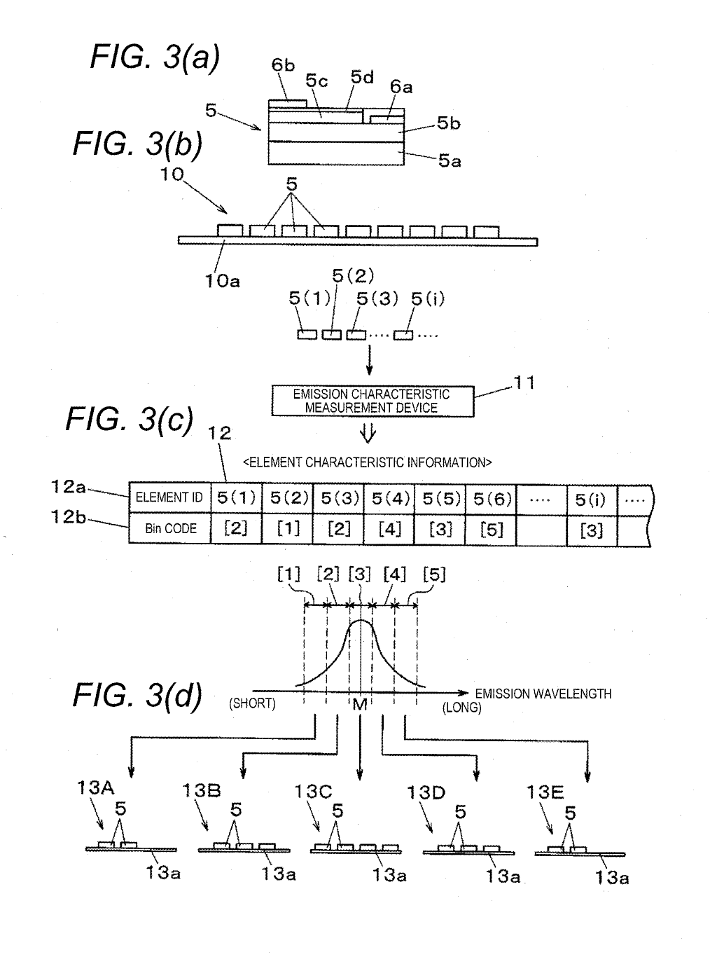

With reference to FIGS. 2 and 3, the substrate 4 and the LED element 5 as work objects in the LED package manufacturing system 1, and an LED package 50 as a completed product are described. As shown in FIG. 2(a), the substrate 4 is a multi-piece substrate which includes a plurality of substrate pieces 4a serving as bases for respective the completed LED packages 50. Each of the substrate pieces 4a includes an LED mounting portion 4b for mounting the LED element 5 thereon. The LED packages 50 shown in FIG. 2(b) are completed by: mounting the LED element 5 in the LED mounting portion 4b of each of the substrate pieces 4a; coating an interior of the LED mounting portion 4b with resin 8 to cover the LED element 5; and cutting the substrate 4 to which the processes have been finished into the substrate pieces 4a after curing of the resin 8.

Each of the LED packages 50 has a function of emitting white light used as a light source of various illuminating devices. The LED element 5 that is a blue LED is combined with the resin 8 containing phosphor which emits yellow fluorescent light which is a complementary color of blue, whereby pseudo white light is produced. As shown in FIG. 2(b), the substrate piece 4a includes a cavity-shaped reflection portion 4c, for example, with a circular or oval annular dike, which defines the LED mounting portion 4b. The LED element 5 mounted on the reflection portion 4c includes an N-type electrode 6a and a P-type electrode 6b which are connected to a wiring layer 4e and a wiring layer 4b formed on an upper surface of the substrate piece 4a by bonding wires 7, respectively. The LED element 5 in this state is covered by coating the reflection portion 4c with the resin 8 to have a predetermined thickness. During the course of irradiation of blue light emitted from the LED element 5 through the resin 8, the blue light is mixed with yellow light emitted from the phosphor contained in the resin 8, whereby white light is irradiated.

As shown in FIG. 3(a), the LED element 5 includes an N-type semiconductor 5b and a P-type semiconductor 5c which are laminated in this sequence on a sapphire substrate 5a; and a transparent electrode 5d covering a surface of the P-type semiconductor 5c. The N-type electrode 6a and the P-type electrode 6b for external connection are formed on the N-type semiconductor 5b and the P-type semiconductor 5c, respectively. As shown in FIG. 3(b), the plurality of LED elements 5 are collectively produced. Thereafter, the LED elements 5 are picked up from an LED wafer 10 while being separated into pieces adhered and held by a holding sheet 10a. Due to various error factors in the manufacturing process, for example, uneven composition occurring at formation of a film on the wafer, variations in emission characteristic such as emission wavelength inevitably cause in the LED elements 5 separated as pieces from the wafer. If such LED elements 5 are mounted, as they are, on the respective substrates 4, variations will occur in emission characteristics of the LED packages 50 as completed products.

In order to prevent occurrence of a quality defect caused by variations in emission characteristics, according to the embodiment: emission characteristics of the plurality of LED elements 5 manufactured through the same manufacturing processes are preliminarily measured; element characteristic information in which the LED elements 5 are associated with data indicating emission characteristics of the respective LED elements 5 is preliminarily prepared; and at coating of the resin 8, each of the LED elements 5 is coated with an appropriate amount of the resin 8 in accordance with the emission characteristic of the LED element 5. For coating the appropriate amount of resin 8, resin coating information described later is previously prepared.

First, the element characteristic information is described. As shown in FIG. 3(c), each of the LED elements 5 picked up from the LED wafer 10 is given an element ID for identifying an individual LED element 5 (in the embodiment, an individual LED element 5 is identified by a serial number (i) in the LED wafer 10), and the LED elements 5 with the element IDs are sequentially loaded into an emission characteristic measurement device 11. The element ID may be defined by another format so long as the information enables individual identification of the LED element 5, for example, matrix coordinates showing an array of the LED elements 5 on the LED wafer 10 may be used as it is. By using the element ID of the format, the LED elements 5 can be supplied in the form of the LED wafer 10 in the component mounting device M1 described later.

In the emission characteristic measurement device 11, electric power is supplied to each of the LED elements 5 by a probe such that the LED element 5 actually emit light, and the emitted light is subjected to spectroscopic analysis and is measured for predetermined items such as an emission wavelength and emission intensity. For the LED element 5 as a measurement object, a standard distribution of an emission wavelength is preliminarily prepared as reference data, and a wavelength range corresponding to a standard range in the distribution is divided into a plurality of wavelength regions. Accordingly, the plurality of LED elements 5 as measurement objects are classified according to an emission wavelength. In the embodiment, ranks are set by classifying a wavelength range into five regions, and Bin codes [1], [2], [3], [4] and [5] are assigned to the ranks in sequence from a lower wavelength, respectively. Consequently, element characteristic information 12 having a data configuration associating the element ID 12a with the Bin code 12b is created.

Specifically, the element characteristic information 12 is obtained by preliminarily, individually measuring emission characteristics including respective emission wavelengths of the plurality of LED elements 5. The element characteristic information 12 is preliminarily prepared by an LED element manufacturer and is transmitted to the LED package manufacturing system 1. As a form of transmission of the element characteristic information 12, the element characteristic information 12 may be transmitted while recorded in a single storage medium, or may be transmitted to the management computer 3 via the LAN system 2. In any event, the transmitted element characteristic information 12 is stored in the management computer 3 and provided to the component mounting device M1, as required.

The plurality of LED elements 5 for which emission characteristic measurement has been finished are sorted into five types of characteristic ranks as shown in FIG. 3(d). The sorted LED elements 5 are respectively affixed to five adhesive sheets 13a. Five types of LED sheets 13A, 13B, 13C, 13D, and 13E are prepared so as to corresponding to the respective Bin codes [1], [2], [3], [4], and [5]. In the LED sheets 13A, 13B, 13C, 13D, and 13E, the LED elements 5 are adhered to and held by the adhesive sheets 13a. When the LED elements 5 are mounted on the substrate pieces 4a of the substrate 4, the LED elements 5 are supplied to the component mounting device M1 in the form of the LED sheets 13A, 13B, 13C, 13D, and 13E which have already been ranked. At this time, the management computer 3 provides the element characteristic information 12 in the form to indicate which of the Bin codes [1], [2], [3], [4], and [5] corresponds to the LED elements 5 held on the LED sheets 13A, 13B, 13C, 13D and 13E.

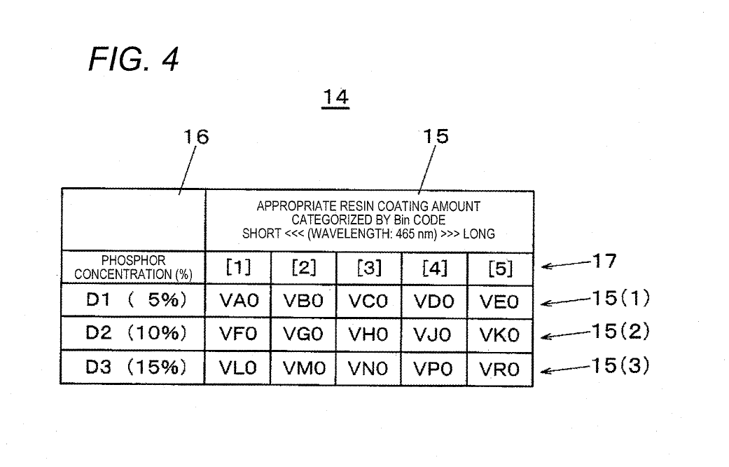

Next, the resin coating information preliminarily prepared to correspond to the element characteristic information 12 is described with reference to FIG. 4. In the LED package 50 configured to generate white light by the combination of the blue LED with the YAG-based phosphor, the blue light emitted by the LED element 5 is mixed with yellow light emitted by light of the phosphor excited by the blue light. Therefore, an amount of phosphor particles in the recessed LED mounting portion 4b for mounting the LED element 5 thereon is important for ensuring a regular emission characteristic of the LED package 50 as a product.

As described above, variations classified by the Bin codes [1], [2], [3], [4], and [5] exist in emission wavelengths of the plurality of LED elements 5 which are work objects at the same time. Therefore, an appropriate amount of phosphor particles in the resin 8 coated to cover the LED element 5 is different depending on the Bin codes [1], [2], [3], [4], and [5]. As shown in FIG. 4, in resin coating information 14 prepared in the embodiment, a Bin-code categorized appropriate resin coating amount of the resin 8 containing YAG-based phosphor particles in silicone resin, epoxy resin, or the like is preliminarily specified in nl (nanoliter) according to a Bin code category 17. That is, when the resin 8 is coated to cover the LED element 5 in the appropriate resin coating amount indicated in the resin coating information 14 correctly, the amount of the phosphor particles contained in the resin covering the LED element 5 is an appropriate supply amount of the phosphor particles, whereby the regular emission wavelength required for the completed product after thermal curing of the resin is ensured.

In the embodiment, as indicated in a phosphor concentration field 16, a phosphor concentration representing the concentration of phosphor particles in the resin 8 is set to a plurality of levels (three concentrations D1 (5%), D2 (10%), and D3 (15%) in the embodiment), and the value of the appropriate resin coating amount of resin 8 is used according to the concentration of phosphor in the used resin 8. When the resin of the phosphor concentration D1 is coated, the appropriate resin coating amount VA0, VB0, VC0, VD0, VE0 (an appropriate resin coating amount 15(1)) is coated for the Bin code [1], [2], [3], [4], [5], respectively. Similarly, when the resin of the phosphor concentration D2 is coated, the appropriate resin coating amount VF0, VG0, VH0, VJ0, VK0 (an appropriate resin coating amount 15(2)) is coated for the Bin code [1], [2], [3], [4], [5], respectively. When the resin of the phosphor concentration D3 is coated, the appropriate resin coating amount VL0, VM0, VN0, VP0, VR0 (an appropriate resin coating amount 15(3)) is coated for the Bin code [1], [2], [3], [4], [5], respectively. The reason why the appropriate resin coating amounts are set according to the respective different phosphor concentrations is because coating of the resin 8 having an optimum phosphor concentration according to a degree of variation in emission wavelength is more desirable from the viewpoint of securing quality.

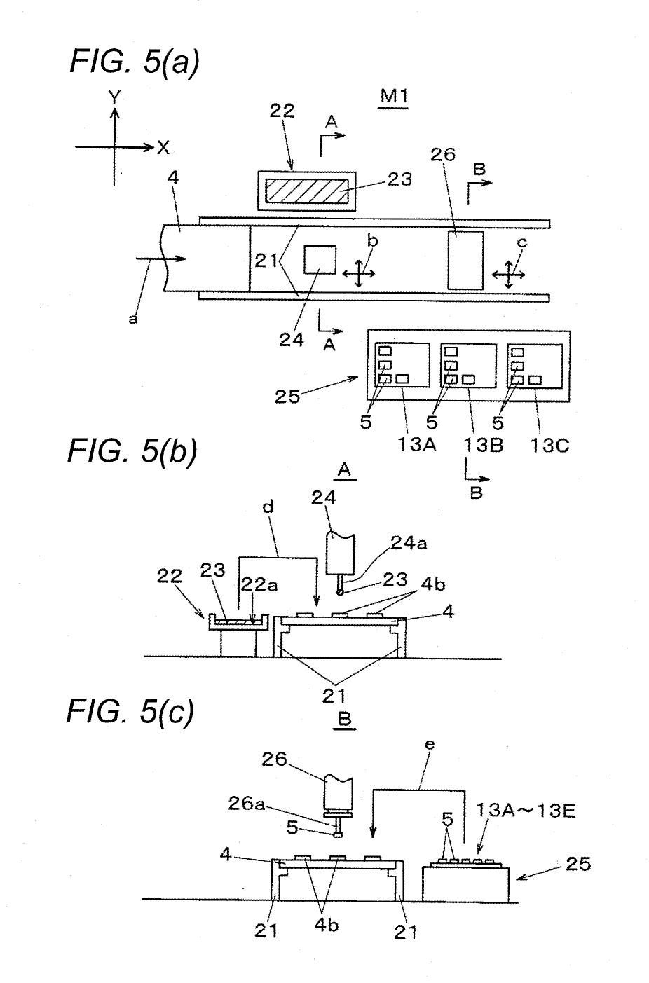

With reference to FIG. 5, a configuration and function of the component mounting device M1 are described. As shown in a plan view of FIG. 5(a), the component mounting device M1 includes a substrate transport mechanism 21 which transports the substrate 4 as a work object, which is supplied from an upstream position, in a substrate transport direction (an arrow “a”). In the substrate transport mechanism 21, an adhesive coating section A illustrated in cross section A-A shown in FIG. 5(b) and a component mounting section B illustrated in cross section B-B shown in FIG. 5(c) are provided in this order from an upstream side. The adhesive coating section A includes: an adhesive supply section 22 which is disposed lateral to the substrate transport mechanism 21 and which supplies resin adhesive 23 in the form of a coating film having a predetermined thickness; and an adhesive transfer mechanism 24 movable in a horizontal direction (an arrow “b”) above the substrate transport mechanism 21 and the adhesive supply section 22. The component mounting section B includes: a component supply mechanism 25 which is disposed lateral to the substrate transport mechanism 21 and which holds the LED sheets 13A, 13B, 13C, 13D, and 13E shown in FIG. 3(d); and a component mounting mechanism 26 movable in the horizontal direction (an arrow “c”) above the substrate transport mechanism 21 and the component supply mechanism 25.

As shown in FIG. 5(b), the substrate 4 carried into the substrate transport mechanism 21 is positioned at the adhesive coating section A, and the resin adhesive 23 is coated on the LED mounting portions 4b formed in the respective substrate pieces 4a as targets. Specifically, the adhesive transfer mechanism 24 is moved to a position above the adhesive supply section 22 such that a transfer pin 24a contacts the coating film of the resin adhesive 23 formed on a transfer surface 22a, whereby the resin adhesive 23 adheres to the transfer pin 24a. Next, the adhesive transfer mechanism 24 is moved to a position above the substrate 4, and the transfer pin 24a is lowered to the LED mounting portions 4b (arrow “d”), whereby the resin adhesive 23 adhering to the transfer pin 24a is supplied to an element mounting position located within the LED mounting portions 4b by transfer.

The substrate 4 coated with the adhesive is transported downstream and positioned at the component mounting section B as shown in FIG. 5(c), and the LED element 5 is mounted to each of the LED mounting portions 4b as a target on which the adhesive has been put. Specifically, the component mounting mechanism 26 is moved to a position above the component supply mechanism 25, and a mounting nozzle 26a is lowered to any one of the LED sheets 13A, 13B, 13C, 13D, and 13E held by the component supply mechanism 25. In this state, the mounting nozzle 26a picks up and holds the LED element 5. Next, the component mounting mechanism 26 is moved to a position above the LED mounting portion 4b of the substrate 4, and then the mounting nozzle 26a is lowered (arrow “e”), whereby the LED element 5 held by the mounting nozzle 26a is mounted on the element mounting position which is located within the LED mounting portion 4b and which is coated with an adhesive.

The component mounting work for mounting the LED element 5 on the substrate 4 by the component mounting device M1 is executed according to a preliminarily-prepared element mounting program. The element mounting program preliminarily sets a sequence of picking up the LED elements 5 from one of the LED sheets 13A, 13B, 13C, 13D, and 13E by an individual mounting operation of the component mounting mechanism 26 to mount the LED elements 5 on the plurality of respective substrate pieces 4a of the substrate 4.

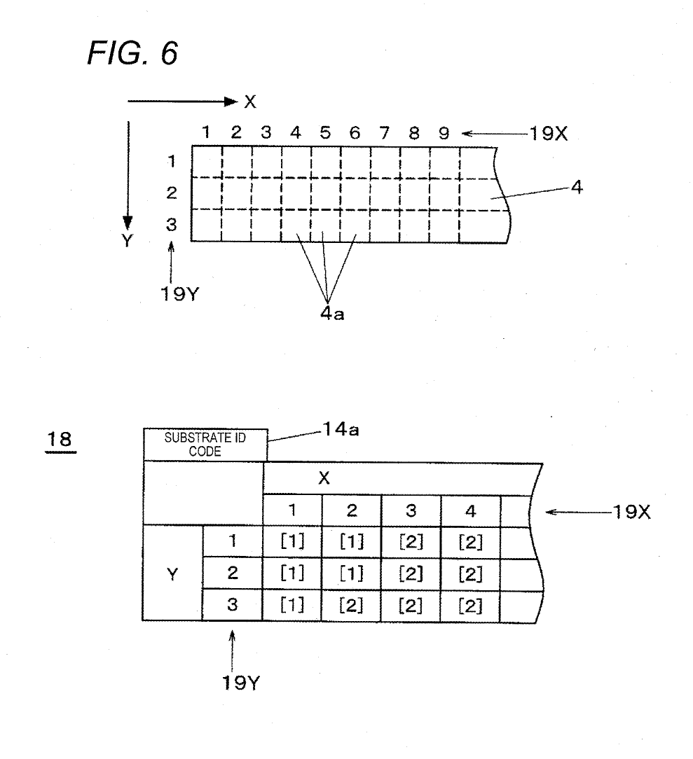

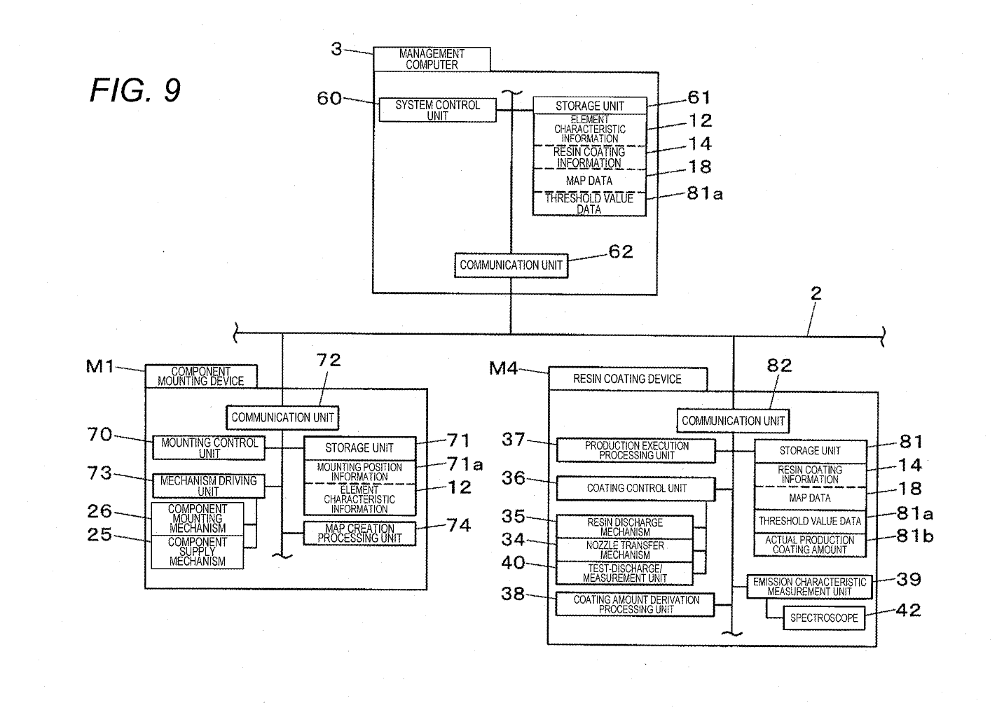

When component mounting work is executed, mounting position information 71a (see FIG. 9) is extracted and recorded. The mounting position information 71a indicates that each of the LED elements 5 is mounted on which one of the plurality of substrate pieces 4a of the substrate 4 from work performance history. A map creation processing unit 74 (see FIG. 9) creates, as map data 18 shown in FIG. 6, data which associate the mounting position information 71a with the element characteristic information 12 indicating which one of characteristic ranks (Bin codes [1], [2], [3], [4], and [5]) corresponds to the individual LED element 5 mounted on the substrate piece 4a.

In FIG. 6, the position of each of the plurality of substrate pieces 4a of the substrate 4 is specified by a combination of matrix coordinates 19X and 19Y indicating a position in the X direction and a position in the Y direction, respectively. An individual cell of matrices defined by the matrix coordinates 19X and 19Y is associated with the Bin code to which the LED element 5 mounted on the corresponding position. Consequently, the map data 18 which associates the mounting position information 71a indicating the position of the LED element 5 mounted on the substrate 4 by the component mounting device M1 with the element characteristic information 12 on the LED element 5 is created.

That is, the component mounting device M1 includes the map creation processing unit 74 serving as map data creation means for creating, for each substrate 4, the map data 18 which associates the mounting position information indicating the position of the LED element 5 mounted on the substrate 4 by the component mounting device M1 with the element characteristic information 12 on the LED element 5. The created map data 18 are transmitted as feedforward data to the resin coating device M4 described later via the LAN system 2.

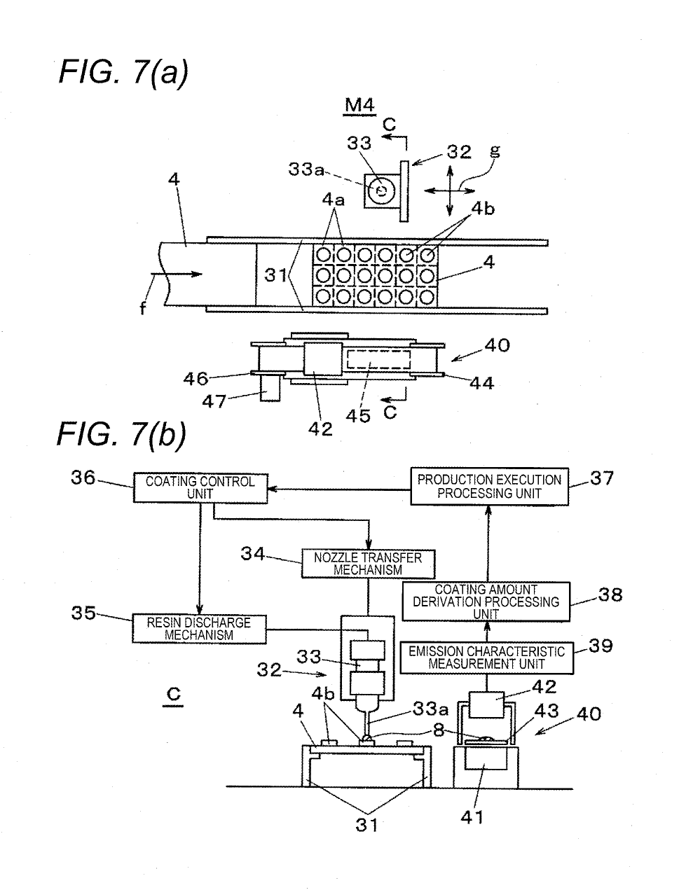

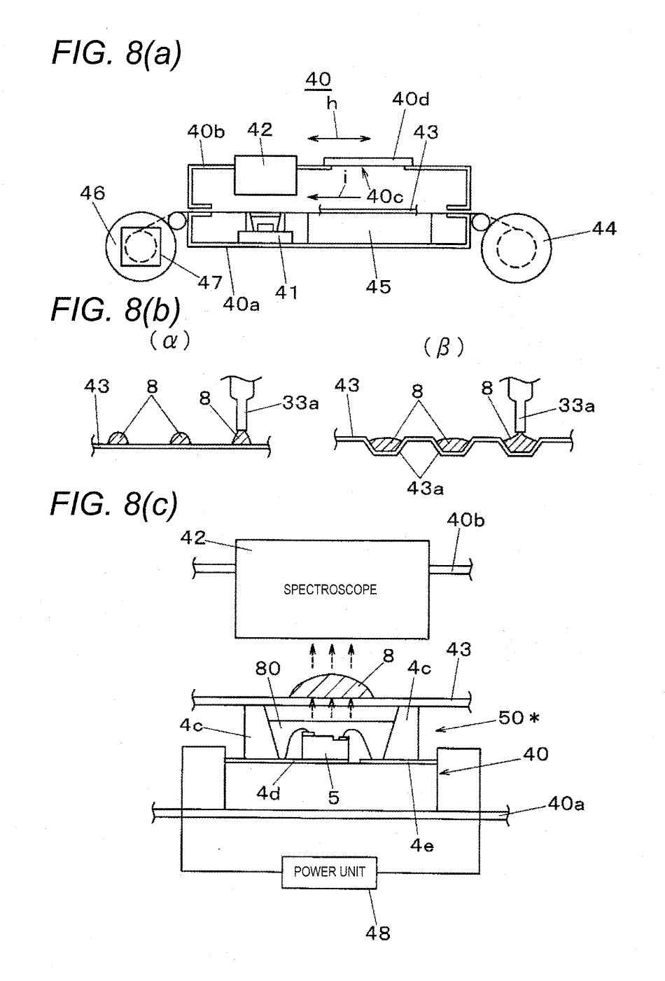

With reference to FIGS. 7 and 8, the configuration and function of the resin coating device M4 are described. The resin coating device M4 has a function of coating, with the resin 8, the plurality of LED elements 5 mounted on the substrate 4 by the component mounting device M1. As shown in a plan view of FIG. 7(a), the resin coating device M4 includes: a substrate transport mechanism 31 which transports the substrate 4 as a work object supplied from an upstream position in a substrate transport direction (arrow “f”); and a resin coating section C illustrated by a cross section C-C shown in FIG. 7(b). The resin coating section C includes a resin discharge head 32 which discharges the resin 8 from a discharge nozzle 33a provided at a lower end thereof.

As shown in FIG. 7(b), the resin discharge head 32 is driven by a nozzle transfer mechanism 34, and the nozzle transfer mechanism 34 is controlled by a coating control unit 36, whereby the resin discharge head 32 performs the move operation in the horizontal direction (the arrow “g” shown in FIG. 7(a)) and lifting and lowering operation. The resin 8 is supplied to the resin discharge head 32 in a sate in which the resin 8 is stored in a syringe loaded to a dispenser 33. When pneumatics is applied to an inside of the dispenser 33 by a resin discharge unit mechanism 35, the resin 8 in the dispenser 33 is discharged through the discharge nozzle 33a, and coated on the LED mounting portion 4a formed on the substrate 4. At this time, the discharge amount of the resin 8 can be arbitrarily controlled by controlling the resin discharge mechanism 35 by the coating control unit 36. In other words, the resin coating section C has a function of discharging the resin 8 by variably adjusting the amount thereof and coating an arbitrary coating target position with the resin.

Lateral to the substrate transport mechanism 31, a test-discharge/measurement unit 40 is disposed within a movable range of the resin discharge head 32. The test-discharge/measurement unit 40 has a function of determining whether the coating amount of the resin 8 is appropriate or not by measuring an emission characteristic of the test-coated resin 8 before an actual production coating work in which the LED mounting portion 4b of the substrate 4 is coated with the resin 8. Specifically, an emission characteristic measurement unit 39 measures the emission characteristic when a light-transmitting member 43 with the resin 8 test-coated thereon by the resin coating section C is irradiated with light from a measurement light source, and the measurement result is compared with a predetermined threshold value. Consequently, a coating amount derivation processing unit 38 determines whether the prescribed resin coating amount specified in the resin coating information 14 shown in FIG. 4 is appropriate or not.

The composition and property of the resin 8 containing phosphor particles is not always stable. Therefore, even when the appropriate resin coating amount is preliminarily set in the resin coating information 14, the variation of concentration of phosphor and viscosity of the resin is inevitable with the lapse of time. Consequently, even when the resin 8 is discharged in accordance with a discharge parameter corresponding to the preliminarily set appropriate resin coating amount, the resin coating amount per se is deviated from the preliminarily set appropriate value, or the supply amount of the phosphor particles to be normally supplied may vary due to change of concentration even when the resin coating amount per se is appropriate.

In order to overcome the disadvantage, according to the embodiment, the test coating is executed at predetermined intervals by the resin coating device M4 to inspect whether the appropriate supply amount of the phosphor particles are supplied or not, and then the measurement of emission characteristic is executed for the test-coated resin as a target. Consequently, the supply amount of the phosphor particles is stabilized based on the proper emission characteristic. The resin coating section C provided in the resin coating device M4 of the embodiment has a function of executing a measurement coating process in which the light-transmitting member 43 is test-coated with the resin 8 for measuring the emission characteristic and a production coating process in which the LED element 5 is coated with the resin 8 for the actual production. The measurement coating process and the production coating process are executed by controlling the resin coating section C by the coating control unit 36.

As shown in FIG. 8, the test-discharge/measurement unit 40 has an external configuration in which a cover portion 40b is provided. The cover portion 40b includes a coating slide window 40c which is slidable (arrow “h”) relative to a base portion 40a having a horizontal elongated shape. The test-discharge/measurement unit 40 includes therein: a test-discharge stage 45 which support the light-transmitting member 43 from below; a light-transmitting member placing section 41 on which the light-transmitting member 43 is to be mounted; and a spectroscope 42 provided above the light-transmitting member placing section 41. The light-transmitting member placing section 41 includes a light source unit which emits excitation light which excites the phosphor. In the measurement coating process, the light-transmitting member 43 with the test-coated resin 8 is irradiated with the excitation light from below by the light source unit.

In the embodiment, the LED element 5 sealed by the resin 8 not containing phosphor is used as the light source unit. Consequently, the emission characteristic of the test-coated resin 8 can be measured by the light having the same characteristic as that of the excitation light emitted by the completed LED package 50. Therefore, higher reliable measurement result can be obtained. It is not necessarily use the LED element 5 which is the same as an LED element used in the completed product, and any light source device may be used as the light source unit fro measurement so long as the light source device emits blue light of a uniform wavelength similar to the LED element 5.

The light-transmitting member 43 is wound and stored in a supply reel 44. The light-transmitting member 43 is carried along an upper surface of the test-discharge stage 45 (arrow “i”). Thereafter, the light-transmitting member 43 passes through a position between the light-transmitting member placing section 41 and the spectroscope 42, and then is wounded by a recovery reel 46 driven by a winding motor 47. The light-transmitting member 43 may be a tape member having a predetermined width of a planar sheet member made of transparent resin, or an emboss type including an emboss portion 43a which is provided in the tape member to protrude from an lower surface thereof so as to have a shape corresponding to a recessed shape of the LED package 50.

In a state in which the coating slide window 40c is slid to open, the upper surface of the test-discharge stage 45 is exposed upward, and the light-transmitting member 43 placed on the upper surface is allowed to be test-coated with the resin by the resin discharge head 32. As shown in FIG. 8(b), the test-coating is performed by discharging a specified resin amount of the resin by the discharge nozzle 33a to the light-transmitting member 43 of which a lower surface side is supported by the test-discharge stage 45.

FIG. 8(b)(a) shows a state in which the light-transmitting member 43 of the tape member is coated with the resin 8 in an appropriate discharge amount preliminarily set in the resin coating information 14. Similarly, FIG. 8(b)(β) shows a state in which the emboss portion 43a of the light-transmitting member 43 of the emboss type is coated with the resin 8 in the preliminarily-set appropriate discharge amount. The resin 8 coated at the test-discharge stage 45 is a test coating for demonstratively determining whether the supply amount of the phosphor is appropriate for the LED element 5 as the target or not. Therefore, as described later, when the plurality of positions of the light-transmitting member 43 are sequentially coated with the resin 8 in a single test-coating operation by the resin the resin discharge head 32, the coating amounts are changed in steps based on given data indicating a correlation relationship between a emission characteristic measurement value and the coating amount.

FIG. 8(c) shows a state in which a dark room for the emission characteristic measurement is formed between the base portion 40a and the cover portion 40b, by moving the light-transmitting member 43 test-coated with the resin 8 at the test-discharge stage 45 such that the resin 8 is positioned above the light-transmitting member placing section 41, and then lowering the cover portion 40b. In the light-transmitting member placing section 41, the LED package 50* is used. The LED package 50* is formed by replacing the resin 8 in the LED package 50 with transparent resin 80 not containing phosphor particles. In the LED package 50*, wiring layers 4e, 4d connected to the LED element 5 is connected to a power unit 48. When the power unit 48 is turned on, electric power for emission is supplied to the LED element 5, whereby the LED element 5 emits blue light.

When the blue light is irradiated to the resin 8 test-coated with the light-transmitting member 43 after the blue light passes through the transparent resin 80, the white light formed by mixing the yellow light emitted by exciting the phosphor in the resin 8 and the blue light is irradiated upward. The spectroscope 42 is provided above the test-discharge/measurement unit 4, and receives the white light irradiated from the resin 8. The received white right is analyzed by the emission characteristic measurement unit 39, whereby the emission characteristic is measured. In the embodiment, the emission characteristic such as tone rank and flux of light is inspected, and a deviation from the specified emission characteristic is detected as an inspection result. That is, the emission characteristic measurement unit 39 measures the emission characteristic of the light emitted from the resin 8 coated on the light-transmitting member 43 by irradiating the resin 8 with the excitation light emitted from the LED element 5 as the light source unit.

The measurement result of the emission characteristic measurement unit 39 is transmitted to the coating amount derivation processing unit 38. The coating amount derivation processing unit 38 obtains the deviation between the measurement result of the emission characteristic measurement unit 39 and the prescribed emission characteristic, and derives an appropriate resin coating amount of the resin 8 to be coated on the LED element 8 for the actual production based on the deviation. The new appropriate discharge amount derived by the coating amount derivation processing unit 38 is transmitted to a production execution processing unit 37, and the production execution processing unit 37 informs the coating control unit 36 of the newly derived appropriate resin coating amount. Consequently, the coating control unit 36 controls the nozzle transfer mechanism 34 and the nozzle transfer mechanism 35 such that the resin discharge head 32 executes the production coating process in which the LED element 5 mounted on the substrate 4 is coated with the resin 8 in the appropriate resin coating amount.

In the production coating process, the resin 8 in the appropriate resin coating amount specified by the resin coating information 14 is actually coated, and the emission characteristic is measured in a state in which the resin 8 is uncured. Then, based on the obtained measurement result, a non-defective product range of the emission characteristic measurement value in a case of measuring the emission characteristic of the resin 8 coated in the production coating as a target is set to use the non-defective product range as a threshold value (see threshold data 81a shown in FIG. 9) for a non-defective product determination in the production coating.

In the resin coating method in the LED package manufacturing system according to the embodiment, the LED element 5 is the light source unit for measuring the emission characteristic. Further, an emission characteristic obtained by basing a regular emission characteristic required for a completed product in which the resin 8 coated on the LED element 5 is cured by a difference of the emission characteristic due to an uncured state of the resin 8 is used as the prescribed emission characteristic which serves as a basis for setting the threshold value for the non-defective product determination in the production coating. Consequently, the resin coating amount at the resin coating process for the LED 5 can be controlled based on the regular emission characteristic for the completed product.

With reference to FIG. 9, a configuration of the control system of the LED package manufacturing system 1 is described. Among elements of the devices configuring the LED package manufacturing system 1, FIG. 9 shows elements relating to transmission/reception and updating processes of the element characteristic information 12, the resin coating information 14, the map data 18, and the threshold data 81a in the management computer 3, the component mounting device M1, and the resin coating device M4.

In FIG. 9, the management computer 3 includes a system control unit 60, a storage unit 61, and a communication unit 62. The system control unit 60 controls the overall LED package manufacturing work performed by the LED package manufacturing system 1. The storage unit 61 stores the element characteristic information 12 and the resin coating information 14, and the map data 18 and the threshold value data 81a as required, in addition to programs and data required for control process of the system control unit 60. The communication unit 62 is connected to other units via the LAN system 2 to transmit and receive control signal and data. The element characteristic information 12 and the resin coating information 14 are transmitted from the outside and stored in the storage unit 61 via the LAN system 2 and the communication unit 62 or by a single storage medium such as CD-ROM.

The component mounting device M1 includes a mounting control unit 70, a storage unit 71, a communication unit 72, a mechanism driving unit 73, and the map creation processing unit 74. In order to execute component mounting work by the component mounting device M1, the mounting control unit 70 controls individual units as described below, according to various programs and data stored in the storage unit 71. The storage unit 71 stores the mounting position information 71a and the element characteristic information 12 in addition to programs and data required for control process of the mounting control unit 70. The mounting position information 71a is created from execution history data of mounting operation control performed by the mounting control unit 70. The element characteristic information 12 is transmitted from the management computer 3 via the LAN system 2. The communication unit 72 is connected to other units via the LAN system 2 to transmit and receive control signal and data.

The mechanism driving unit 73 is controlled by the mounting control unit 70, thereby driving the component supply mechanism 25 and the component mounting mechanism 26. Accordingly, the LED elements 5 are mounted on the respective substrate pieces 4a of the substrate 4. The map creation processing unit 74 (map data creation means) performs a process for creating the map data 18 for each substrate 4. In the map data 18, the mounting position information 71a stored in the storage unit 71 and indicating the position of the LED element 5 mounted on the substrate 4 by the component mounting device M1 is associated with the element characteristic information 12 on the LED element 5. Specifically, the map data creation means is provided in the component mounting device M1, and the map data 18 are transmitted from the component mounting device M1 to the resin coating device M4. Alternatively, the map data 18 may be transmitted from the component mounting device M1 to the resin coating device M4 via the management computer 3. In this case, the map data 18 are also stored in the storage unit 61 of the management computer 3 as shown in FIG. 9.

The resin coating device M4 includes the coating control unit 36, the storage unit 81, a communication unit 82, the production execution processing unit 37, the coating amount derivation processing unit 38, and the emission characteristic measurement unit 39. The coating control unit 36 controls the nozzle transfer mechanism 34 configuring the resin coating section C, the resin discharge mechanism 35, and the test-discharge/measurement unit 40, thereby performing a process for executing the measurement coating process in which the light-transmitting member 43 is test-coated with the resin 8 for measuring the emission characteristic and a production coating process in which the LED element 5 is coated with the resin 8 for the actual production.

The storage unit 81 stores the resin coating information 14, the map data 18, the threshold value data 81a, and an actual production coating amount 81 b, in addition to the programs and data required for control process of the coating control unit 36. The resin coating information 14 is transmitted from the management computer 3 via the LAN system 2. Similarly, the map data 18 are transmitted from the component mounting device M1 via the LAN system 2. The communication unit 82 is connected to other units via the LAN system 2, and transmits and receives control signal and data.

The emission characteristic measurement unit 39 performs a process for measuring the emission characteristic of the light emitted from the resin 8 coated on the light-transmitting member 43 by irradiating the resin 8 with the excitation light emitted from the LED element 5 as the light source unit. The coating amount derivation processing unit 38 performs an arithmetic process for obtaining the deviation between the measurement result of the emission characteristic measurement unit 39 and the prescribed emission characteristic, and deriving the appropriate resin coating amount of the resin 8 to be coated on the LED element 8 for the actual production based on the deviation. The production execution processing unit 37 informs the coating control unit 36 of the appropriate resin coating amount derived by the coating amount derivation processing unit 38 to execute the production coating process in which the LED element 5 is coated with the resin 8 in the appropriate resin coating amount.

In the configuration shown in FIG. 9, the devices may not necessarily be provided with processing functions other than functions for executing work operations unique to the devices, for example, the function of the map creation processing unit 74 provided in the component mounting device M1 and the function of the coating information update unit 84 provided in the resin coating device M4. For example, the function of the map creation processing unit 74 and the function of the coating information update unit 84 may be covered by arithmetic processing function belonging to the system control unit 60 of the management computer 3, and necessary signals may be transmitted and received via the LAN system 2.

In the configuration of the LED package manufacturing system 1, the component mounting device M1 and the resin coating device M4 are connected to the LAN system 2. The management computer 3 having the element characteristic information 12 stored in the storage unit 61 and the LAN system 2 serve as element characteristic information providing means for providing information obtained by preliminary measuring emission characteristics including emission wavelengths for each of the plurality of LED elements 5 to the component mounting device M1 as the element characteristic information 12. Similarly, the management computer 3 having the resin coating information 14 stored in the storage unit 61 and the LAN system 2 serve as resin information providing means for providing information in which the appropriate resin coating amount of resin 8 for producing the LED package 50 having a specified emission characteristic with the element characteristic information to the resin coating device M4 as the resin coating information.

That is, the element characteristic information providing means for providing the element characteristic information 12 to the component mounting device M1 and the resin information providing means for providing the resin coating information 14 to the resin contacting device M4 are configured to transmit the element characteristic information and the resin coating information, which is read from the storage unit 61 of the management computer 63 serving as an external storage unit, to the component mounting device M1 and the resin coating device M4 via the LAN system 2, respectively.

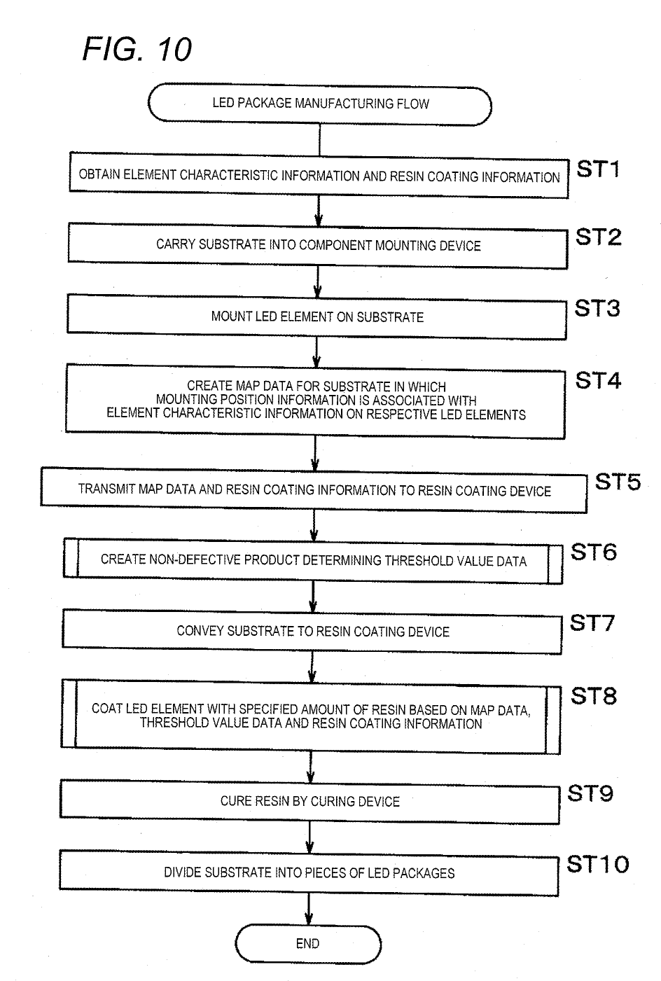

Next, LED package manufacturing processes performed by the LED package manufacturing system 1 is described along a flowchart of FIG. 10 and with reference to the drawings. At first, the LED package manufacturing system 1 obtains the element characteristic information 12 and the resin coating information 14 (ST1). Specifically, the element characteristic information 12 obtained by preliminary measuring emission characteristics including emission wavelengths for each of the plurality of LED elements 5 and the resin coating information 14 in which the element characteristic information 12 is associated with an appropriate coating amount of resin 8 appropriate for producing the LED package 50 having the specified emission characteristic are obtained from an external device via the LAN system 2 or a storage medium.

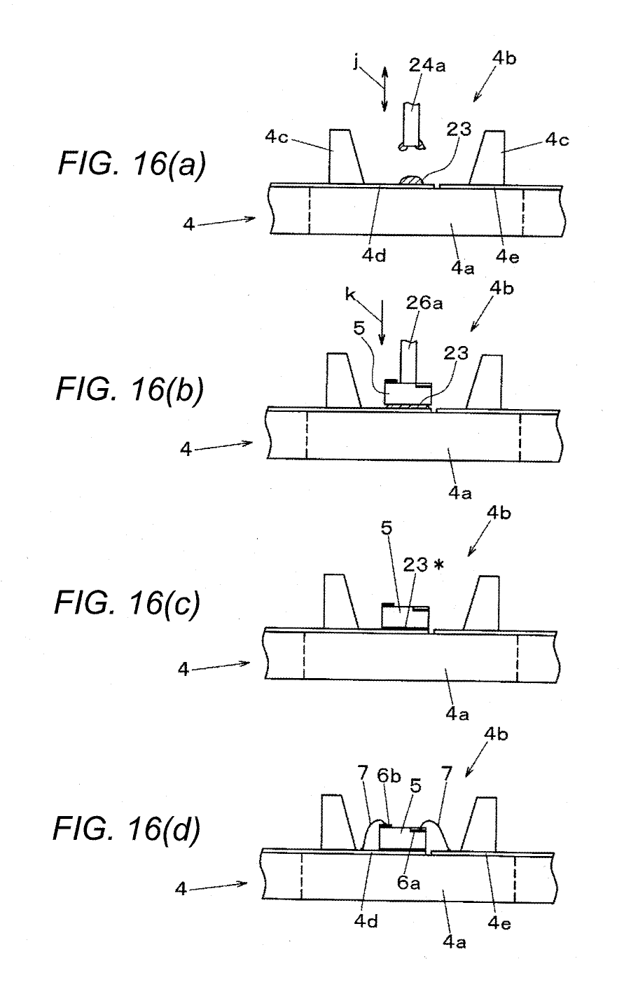

Subsequently, the substrate 4 as a mounting operation object is carried into the component mounting device M1 (ST2). As shown in FIG. 16(a), the resin adhesive 23 is supplied to the element mounting position within the LED mounting portion 4b by lifting and lowering the transfer pin 24a of the adhesive transfer mechanism 24 (arrow “j”). Thereafter, as shown in FIG. 16(b), the LED element 5 held by the mounting nozzle 26a of the component mounting mechanism 26 is lowered (arrow “k”) and mounted on the LED mounting portion 4b of the substrate 4 through the resin adhesive 23 (ST3). From execution data on component mounting work, the map creation processing unit 74 creates the map data 18 associating the mounting position information 71a with the element characteristic information 12 on each of the LED elements 5 for the substrate 4 (ST4). Next, the map data 18 are transmitted from the component mounting device M1 to the resin coating device M4, and the resin coating information 14 is transmitted from the management computer 3 to the resin coating device M4 (ST5). Consequently, the resin coating device M4 can execute resin coating work.

The substrate 4 with the components mounted thereon is sent to the curing device M2, and is heated therein. Consequently, as shown in FIG. 16(c), the resin adhesive 23 is thermally cured and turns into a resin adhesive 23*, whereby the LED element 5 is fixed to the substrate piece 4a. Subsequently, the substrate 4 with the cured resin is sent to the wire bonding device M3. As shown in FIG. 16(d), the wiring layers 4e, 4d of the substrate piece 4a are connected to the N-type electrode 6a and the P-type electrode 6b of the LED element 5 by the bonding wire 7, respectively.

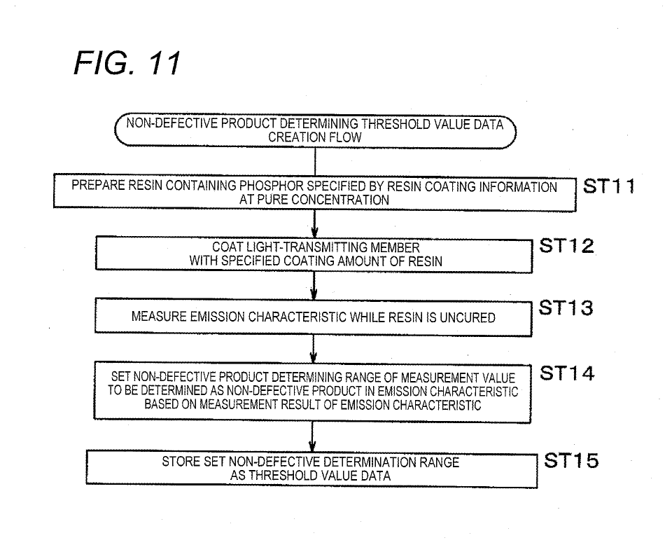

Subsequently, the LED package manufacturing system 1 executes a non-defective product determining threshold value creation process (ST6). The process is executed for setting a threshold value (see threshold data 81a shown in FIG. 9) for a non-defective product determination in the production coating, and repeatedly executed for the production coatings corresponding to Bin codes [1], [2], [3], [4], and [5], respectively. The details of the threshold value data creation process are described with reference to FIGS. 11, 12, and 13. In FIG. 11, at first, the resin 8 containing phosphor specified by resin coating information 14 at pure concentration is prepared (ST11). After the resin 8 is set to the resin discharge head 32, the discharge head 32 is moved to the test-discharge stage 45 of the test-discharge/measurement unit 40, and the light-transmitting member 43 is coated with the resin 8 in the specified coating amount (appropriate resin coating amount) indicated in the resin coating information 14 (ST12). Next, the resin 8 coated on the light-transmitting member 43 is moved to the light-transmitting member placing portion 41, and the LED element 5 is caused to emit light, whereby the emission characteristic in a state in which the resin 8 is uncured is measured by the emission characteristic measurement unit 39 (ST13). Based on an emission characteristic measurement value 39a which is the measurement result of the emission characteristic measured by the emission characteristic measurement unit 39, the non-defective product determining range of the measurement value to be determined as the non-defective product in the emission characteristic is set (ST14). As the threshold value data 81a, the set non-defective product determining range is stored in the storage unit 81, and transmitted to the management computer 3 and stored in the storage unit 61 (ST15).

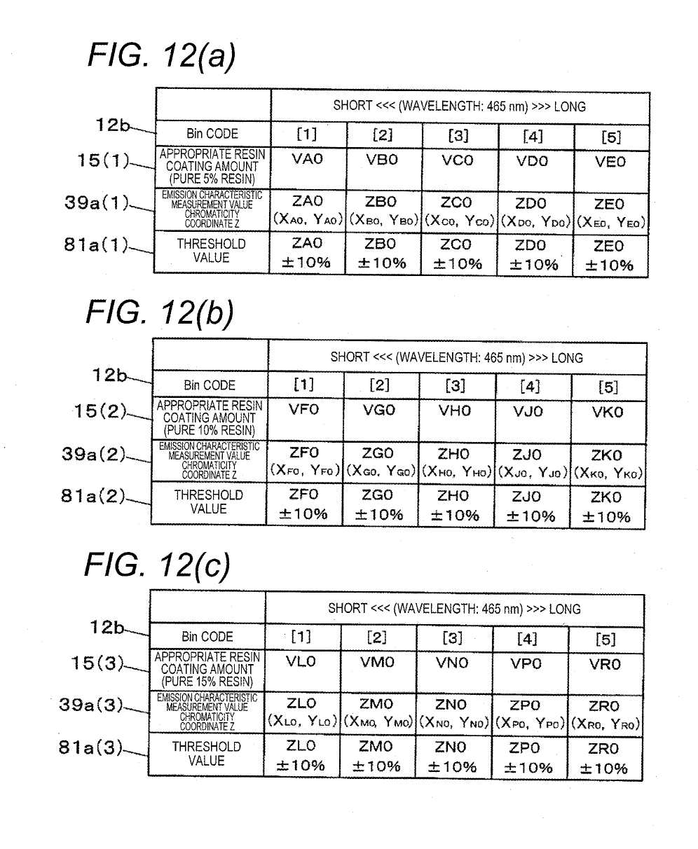

FIG. 12 shows the threshold data created in this way, that is, the emission characteristic measurement value obtained in a resin uncured state after coating of the resin 8 containing the phosphor in a pure amount and the non-defective product determination range (threshold value) of the measurement value to be determined as the non-defective product in the emission characteristic. FIGS. 12(a), 12(b), and 12(c) show threshold values corresponding to the Bin codes [1], [2], [3], [4], and [5], respectively, in case of the phosphor concentration in the resin 8 is 5%, 10% and 15%.

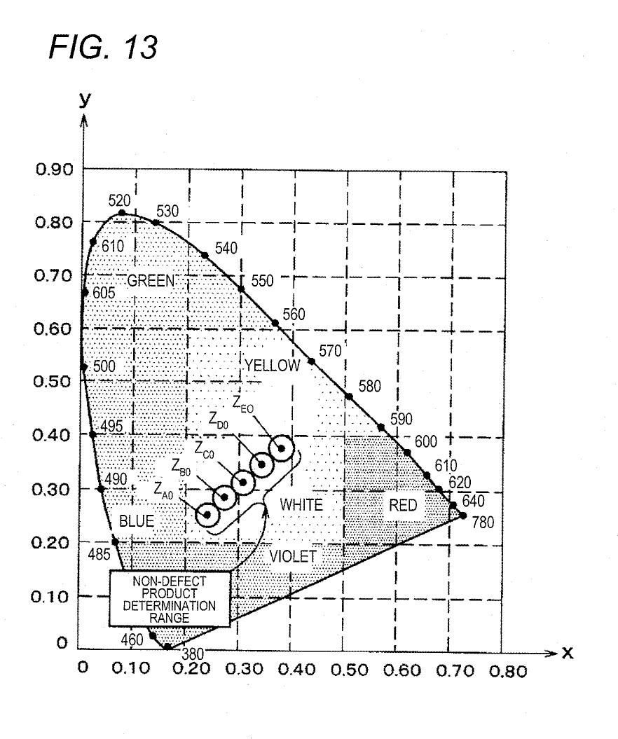

For example, as shown in FIG. 12(a), in a case in which the concentration of the phosphor of the resin 8 is 5%, coating amounts indicated in an appropriate resin coating amount 15(1) correspond to Bin codes of the Bin code 12b, respectively. The measurement results obtained by measuring emission characteristics of the light emitted by the resin 8 by irradiating the resin 8 coated in the respective coating amounts with the blue light of the LED element 5 are indicated in an emission characteristic measurement value 39a(1). Based on the values in the emission characteristic measurement value 39a(1), threshold value data 81a(1) are set. For example, the measurement result obtained by measuring the emission characteristic of the resin 8 as a target coated in an appropriate resin coating amount VA0 corresponding to the Bin code [1] is represented as a chromaticity coordinate ZA0 (XA0, YA0) on the chromaticity diagram shown in FIG. 13. Then, the non-defective product determination range (threshold value) is set to a predetermined range (for example, ±10%) of X-coordinate and Y-coordinate on the chromaticity diagram with the chromaticity coordinate ZA0 as its center. The non-defective product determination ranges (threshold values) are set similarly for the appropriate resin coating amounts of other Bin codes [2]-[5] based on the emission characteristic measurement results (see chromaticity coordinates ZB0-ZE0 on the chromaticity diagram shown in FIG. 13). The predetermined range as the threshold value is set appropriately in accordance with an accuracy level of the emission characteristic required for the LED package 50 as a product.

Similarly, FIGS. 12(b) and 12(c) indicate the emission characteristic measurement values and the non-defective determination ranges (threshold values) in cases in which the concentrations of the phosphor of the resin 8 are 10% and 15%, respectively. In FIGS. 12(b) and 12(c), an appropriate resin coating amount 15(2) and an appropriate resin coating amount 15(3) indicate appropriate resin coating amounts in cases in which the concentrations of the phosphor are 10% and 15%, respectively. Further, an emission characteristic measurement value 39a(2) and an emission characteristic measurement value 39a(3) indicate the emission characteristic measurement values in cases in which the concentrations of the phosphor are 10% and 15%, respectively, and threshold value data 81(2) and threshold value data 81(3) indicate non-defective determination ranges (threshold values) in the respective cases. The threshold data created in this way are selected in accordance with the Bin code 12 to which the LED element 5 as a target in the production coating work. The threshold data creation process shown in (ST6) may be executed by an offline work of a single inspection device separated from the LED package manufacturing system 1 to preliminarily store the threshold data 81a in the management computer 3 such that the threshold data 81a can be transmitted to the resin coating device M4 via the LAN system 2 for use.

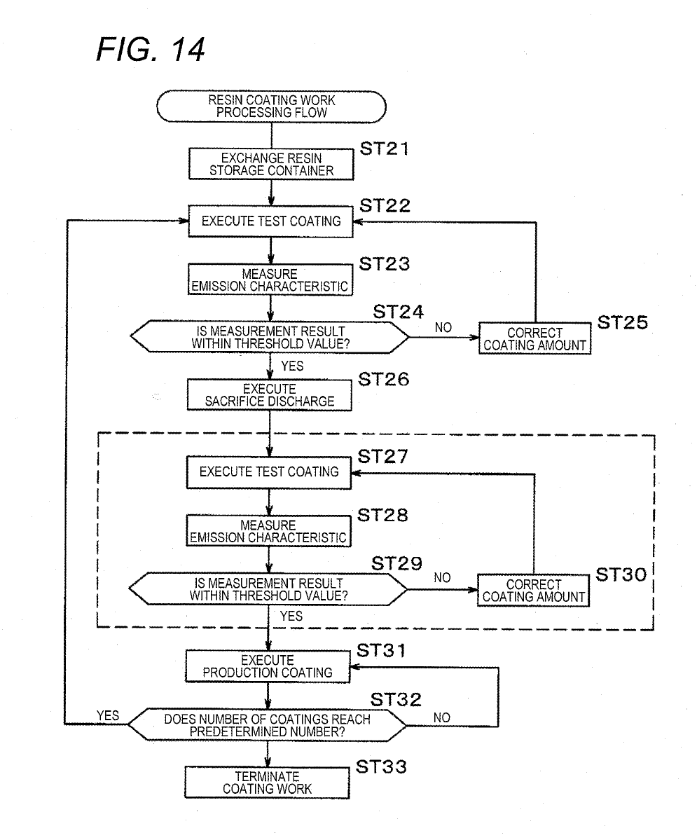

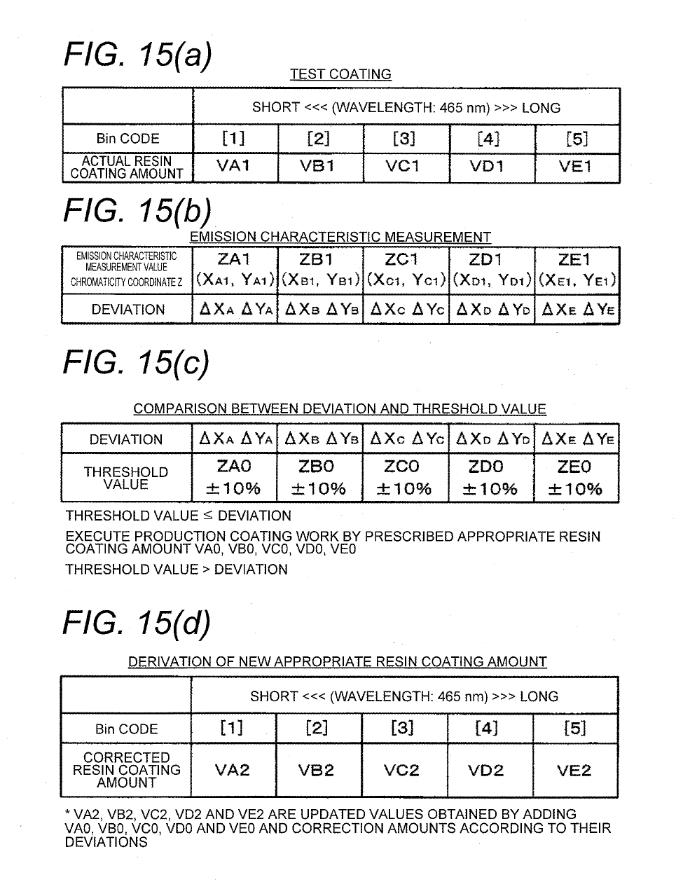

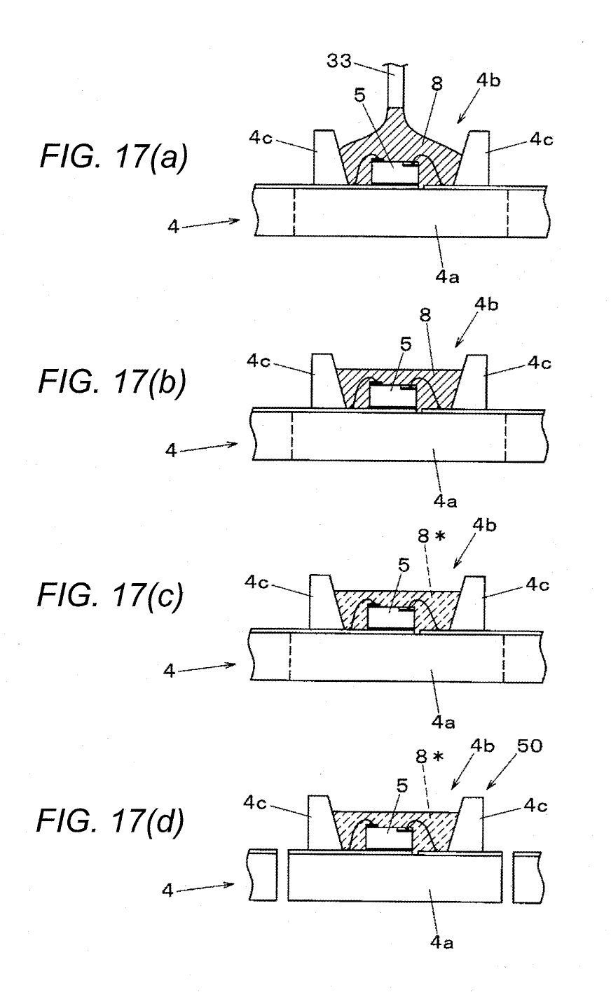

Thereafter, the substrate 4 after wire bonding is carried to the resin coating device M4 (ST7), and as shown in FIG. 17(a), the resin 8 is discharged from the discharge nozzle 33a into the inside of the LED mounting portion 4b surrounded by the reflection portion 4c. In the embodiment, the work for coating the resin 8 of the specified amount shown in FIG. 17(b) to cover the LED 5 is executed based on the map data 18, the threshold data 81a, and the resin coating information 14. Details of the resin coating work process are described with reference to FIGS. 14 and 15. At start of the resin coating work, the resin storage container is exchanged as required (ST21). Specifically, the dispenser 33 attached to the resin discharge head 32 is exchanged to the one which stores the resin 8 having the phosphor concentration selected in accordance with the characteristic of the LED element 5.

Next, the resin coating section C test-coats the light-transmitting member 43 with the resin 8 for the emission characteristic measurement (a measurement coating step) (ST22). Specifically, the light transmitting member 43 fed to the test-discharge stage 45 in the test-discharge/measurement unit 40 is coated with the resin 8 of the appropriate resin coating amounts (VA0-VE0) for the respective Bin codes 12b specified in FIG. 4. However, even when the resin discharge mechanism 35 is informed of the discharge operation parameter corresponding to the appropriate resin coating amounts (VA0-VE0), the actual resin coating amount of the resin discharged from the discharge nozzle 33a and coated on the light-transmitting member 43 does not always become the above-described appropriate resin coating amount due to time-dependent change of the property of the resin 8. As shown in FIG. 15(a), the actual resin coating amounts are VA1-VE1 somewhat different from VA0-VE0.

Subsequently, the light-transmitting member 43 is conveyed in the test-discharge/measurement unit 40, whereby the light-transmitting member 43 with the test-coated resin 8 is conveyed and placed on the light-transmitting member placing section 41 which includes the LED element 5 serving as the light source unit which emits excitation light which excites the phosphor (a light-transmitting member placing step). Next, the resin 8 coated on the light-transmitting member 43 is irradiated with the excitation light emitted from the LED element 5, and the light emitted by the resin 8 is received by the spectroscope 42, whereby the emission characteristic of the light is measured by the emission characteristic measurement unit 39 (an emission characteristic measurement step) (ST23).

Consequently, as shown in FIG. 15(b), the emission characteristic measurement value indicated in the chromaticity coordinate Z (see FIG. 13) is obtained. The measurement result does not always coincide with the prescribed emission characteristic, i.e., the standard chromaticity coordinates ZA0-ZE0 at the appropriate resin coating as shown in FIG. 12(a), due to the error in the coating amount and the change in the concentration of the phosphor particles in the resin 8. Therefore, the coating amount derivation processing unit 38 obtains the deviations (ΔXA, ΔYA) to (ΔXE, ΔYE) which indicates distances of the X-coordinates and the Y-coordinates between the obtained chromaticity coordinates ZA1-ZE1 and the standard chromaticity coordinates ZA0-ZE0 at the appropriate resin coating shown in FIG. 12(a), and determines the necessity of correction to obtain the desired emission characteristic.

In this embodiment, it is determined whether the measurement result is within the threshold value (ST24). Specifically, as shown in FIG. 15(c), the coating amount derivation processing unit 38 compares the deviations obtained at (ST23) and the threshold value, thereby determining whether the deviations (ΔXA, ΔYA) to (ΔXE, ΔYE) are within the ±10% range of ZA0-ZE0. If the deviations are within the threshold value, the discharge operation parameters corresponding to the prescribed appropriate resin coating amount VA0-VE0 are maintained. In contrast, if the deviations are outside the threshold value, the coating amount is corrected (ST25). That is, the coating amount derivation processing unit 38 executes a process for obtaining the deviation between the measurement result at the emission characteristic measurement step and the prescribed emission characteristic, and deriving the new appropriate resin coating amount (VA2-VE2) of the resin 18 to be coated on the LED element 5 for the actual production based on the obtained deviation (a coating amount derivation processing step).

The corrected appropriate resin coating amounts (VA2-VE2) are updated values obtained by adding correction amounts in accordance with the deviations to the respective prescribed appropriate resin coating amounts VA0-VE0. The relationship between the deviation and the correction amount is recorded in the resin coating information 14 in advance as given accompanying data. The processes (ST22), (ST23), (ST24), and ST(25) are repeatedly executed based on the corrected appropriate resin coating amount (VA2-VE2), and if the deviation between the measurement result and the prescribed emission characteristic is confirmed to be within the threshold value at (ST24), the appropriate resin coating amount for actual production is fixed. That is, in the resin coating method described above, the appropriate resin coating amount is finally derived by repeatedly executing the measurement coating step, the light-transmitting placing step, the emission characteristic measurement step, and the coating amount derivation processing step. The fixed appropriate resin coating amount is stored in the storage unit 81 as the actual production coating amount 81b.

Thereafter, the process proceeds to a next step, and a sacrifice discharge is executed (ST26). In the embodiment, the predetermined amount of the resin 8 is discharged from the discharge nozzle 33a, whereby the state of flow of the resin in a resin discharge path is improved to stabilize the operation of the dispenser 33 and the resin discharge mechanism 35. The processes indicated by a box with broken line in FIG. 14, i.e., (ST27), (ST28), (ST29), and (ST30) are identical with the process contents of (ST22), (ST23), (ST24), and (ST25). Therefore, the processes of (ST27), (ST28), (ST29), and (ST30) are executed when it is necessary to carefully confirm that the desired emission characteristic is completely ensured, and are not always essential execution items.

After the appropriate resin coating amount providing the desired emission characteristic is fixed, a production coating is executed (ST31). Specifically, the production execution processing unit 37 informs the coating control unit 36 controlling the resin discharge mechanism 35 of the appropriate resin coating amount derived by the coating amount derivation processing unit 38 and stored as the actual production coating amount 81b, thereby executing the production coating process to coat the LED element 5 mounted on the substrate 4 with the appropriate resin coating amount of the resin 8 (a production execution step).

In the course of repeatedly executing the production coating process, the number of coatings by the dispenser 33 is counted to monitor whether the number of coatings reaches a predetermined number of times (ST32). Until the number of coatings reaches the predetermined number of times, the change in the property of the resin 8 and the phosphor concentration is determined to be small, and the production coating (ST31) is repeatedly executed while the same actual production coating amount 81b is maintained. If the number of coatings is confirmed to reach the predetermined number of times at (ST32), the possibility to change the property of the resin 8 and the phosphor concentration is determined is determined to exist, and the process returns to (ST22) to repeatedly execute the measurement of the emission characteristic and the coating amount correction process based on the measurement result described above.

After the resin coating for one sheet of the substrate 4 is finished, the substrate 4 is sent to the curing device M5 and is heated by the curing device M5, thereby curing the resin 8 (ST8). Consequently, as shown in FIG. 17(c), the resin 8 coated to cover the LED element 5 is thermally cured and turns into resin 8*, whereby the resin 8 becomes in a fixed state within the LED mounting portion 4b. The substrate 4 with the cured resin is sent to the piece cutting device M6, and the substrate 4 is cut into the substrate pieces 4a therein, thereby divided into the pieces of LED packages 50 (ST9) as shown in FIG. 17(d). Accordingly, the LED packages 50 are completed.

As described above, the LED package manufacturing system 1 of the embodiment includes: the component mounting device M1 which mounts the plurality of LED elements 5 on the substrate 4; the element characteristic information providing means for providing, as the element characteristic information 12, information obtained by preliminarily measuring the emission wavelength of each of the plurality of LED elements 5; the resin information providing means for providing, as the resin coating information 14, information in which the appropriate coating amount of resin 8 for producing the LED packages 50 having the specified emission characteristic is associated with the element characteristic information 12; the map data creation means for creating, for each substrate 4, the map data 18 in which the mounting position information 71 a indicating the position of the LED element 5 mounted on the substrate 4 by the component mounting device M1 is associated with the element characteristic information 12 on the LED element 5; and the resin coating device M4 which coats each of the LED elements mounted on the substrate 4 with the appropriate coating amount of resin 8 for exhibiting the specified emission characteristic according to the map data 18 and the resin coating information 14.

The resin coating device M4 includes: a resin coating section C which discharges the resin 8 by variably adjusting the amount thereof and which coats the arbitrary coating target position with the resin 8; the coating control unit 36 which controls the resin coating section C to execute the measurement coating process in which the light-transmitting member 43 is test-coated with the resin 8 for measuring the emission characteristic and the production coating process in which the LED element is coated with the resin 8 for the actual production; the light-transmitting member placing section 41 which includes the light source unit which emits the excitation light which excites the phosphor, and on which the light-transmitting member 43 coated with the test-coated resin 8 is to be placed in the measurement coating process; the emission characteristic measurement unit 39 which measures the emission characteristic of light emitted from the resin 8 coated on the light-transmitting member 43 by irradiating the resin 8 with the excitation light emitted from the light source unit; the coating amount derivation processing unit 38 which obtains the deviation between the measurement result of the emission characteristic measurement unit 39 and the prescribed emission characteristic, and which derives the appropriate resin coating amount of the resin 8 to be coated on the LED element 5 for the actual production by correcting the appropriate resin coating amount based on the deviation; and the production execution processing unit 37 which informs the coating control unit 36 of the derived appropriate resin coating amount to execute the production coating process to coat the LED element 5 with the appropriate resin coating amount of the resin.

With this configuration, in the resin coating used for manufacturing the LED package 52 including the LED element 5 coated with the resin containing phosphor, the light-transmitting member 43 test-coated with the resin 8 for the emission characteristic measurement on the light-transmitting member placing section 41 including the light source unit, and the deviation between the measurement result of the emission characteristic of light emitted from the resin coated on the light-transmitting member 43 measured by irradiating the resin with the excitation light emitted from the light source unit and the prescribed emission characteristic is obtained, whereby the appropriate resin coating amount of the resin to be coated on the LED element for the actual production can be derived based on the deviation. Consequently, it is possible to maintain a uniform emission characteristic of LED packages 50 even when emission wavelengths of pieces of LED elements 5 vary, thereby improving production yield.

The above description shows the LED package manufacturing system 1 in which the management computer 3 and devices from the component mounting device M1 to the piece cutting device M6 are connected by the LAN system 2. However, the LAN system 2 is not always an essential element. Specifically, the function of the LED package manufacturing system 1 of the embodiment can be obtained so long as the LED package manufacturing system 1 includes storage means for the element characteristic information 12 and the resin coating information 14 for each of the LED packages 50, which is prepared in advance and transmitted from the outside; and data providing means capable of providing the element characteristic information 12 to the component mounting device M1 and the resin coating information 14 and the map data 18 to the resin coating device M4 from the storage means as requested.

In the present invention, various changes and applications are scheduled to be made by a skilled person without departing from the spirit and scope of the present invention based on the descriptions of the specification and known techniques, and should be within the scope of protection to be sought for of the invention. Further, the elements described in the embodiment may be arbitrarily combined without departing from the sprit of the present invention.

The present patent application is based on Japanese Patent Application (Application No. 2010-240467) filed on Oct. 27, 2010, the entire content of which is incorporated herein by reference.

### INDUSTRIAL APPLICABILITY

The resin coating device and the resin coating method provides an advantage of maintaining a uniform emission characteristic of the LED packages even when emission wavelengths of pieces of LED elements vary, thereby improving production yield, and can be used in a field of manufacture of an LED package including an LED element coated and covered with resin containing phosphor.

### DESCRIPTION OF REFERENCE SIGNS

1 LED PACKAGE MANUFACTURING SYSTEM
2 LAN SYSTEM
4 SUBSTRATE
4a SUBSTRATE PIECE
4b LED MOUNTING PORTION
5 LED ELEMENT
8 RESIN
12 ELEMENT CHARACTERISTIC INFORMATION
13A, 13B, 13C, 13D, 13E LED SHEET
14 RESIN COATING INFORMATION
18 MAP DATA
23 RESIN ADHESIVE INFORMATION
24 ADHESIVE TRANSFER MECHANISM
25 COMPONENT SUPPLY MECHANISM
26 COMPONENT MOUNTING MECHANISM
32 RESIN DISCHARGE HEAD
33 DISPENSER
33a DISCHARGE NOZZLE
40 TEST-DISCHARGE/MEASUREMENT UNIT
41 LIGHT-TRANSMITTING MEMBER PLACING SECTION
42 SPECTROSCOPE
43 LIGHT-TRANSMITTING MEMBER
45 TEST-DISCHARGE STAGE
50 LED PACKAGE

1. A resin coating device which is used in an LED package manufacturing system for manufacturing an LED package comprising an LED element mounted on a substrate and coated with resin containing phosphor, and which coats the LED element mounted on the substrate with the resin, said resin coating device comprising:
a resin coating section which discharges the resin by variably adjusting an amount thereof and which coats an arbitrary coating target position with the resin;
a coating control unit which controls the resin coating section to execute a measurement coating process in which a light-transmitting member is test-coated with the resin for measuring an emission characteristic and a production coating process in which the LED element is coated with the resin for an actual production;
a light-transmitting member placing section which comprises a light source unit which emits excitation light which excites the phosphor, and on which the light-transmitting member coated with the test-coated resin is to be placed in the measurement coating process;
an emission characteristic measurement unit which measures an emission characteristic of light emitted from the resin coated on the light-transmitting member by irradiating the resin with the excitation light emitted from the light source unit;
a coating amount derivation processing unit which obtains a deviation between a measurement result of the emission characteristic measurement unit and a prescribed emission characteristic, and which derives an appropriate resin coating amount of the resin to be coated on the LED element for the actual production based on the deviation; and
a production execution processing unit which informs the coating control unit of the appropriate resin coating amount to execute the production coating process to coat the LED element with the appropriate resin coating amount of the resin.

2. The resin coating device according to claim 1,
wherein an LED element is used as the light source unit.

3. A resin coating method which is used in an LED package manufacturing system for manufacturing an LED package comprising an LED element mounted on a substrate and coated with resin containing phosphor, and which coats the LED element mounted on the substrate with the resin, said resin coating method comprising:
a measurement coating step of test-coating a light-transmitting member with the resin by a resin coating section which discharges the resin by variably adjusting an amount thereof;
a light-transmitting member placing step of mounting the light-transmitting member coated with the test-coated resin on a light-transmitting member placing section which comprises a light source unit which emits excitation light which excites the phosphor;
an emission characteristic measurement step of measuring an emission characteristic of light emitted from the resin coated on the light-transmitting member by irradiating the resin with the excitation light emitted from the light source unit;
a coating amount derivation processing step of obtaining a deviation between a measurement result of the emission characteristic measurement unit and a prescribed emission characteristic, and deriving an appropriate resin coating amount of the resin to be coated on the LED element for an actual production based on the deviation; and
a production execution step of executing a production coating process to coat the LED element with the appropriate resin coating amount of the resin by informing a coating control unit controlling the resin coating section of the appropriate resin coating amount.

4. The resin coating method according to claim 3,
wherein an LED element sealed by resin not containing phosphor is used as the light source unit,
wherein the prescribed emission characteristic is obtained such that a regular emission characteristic required for a completed product in which the resin coated on the LED element is cured is biased by a difference of the emission characteristic due to an uncured state of the resin.

5. The resin coating method according to claim 3,
wherein the appropriate resin coating amount is finally derived by repeatedly executing the measurement coating step, the light-transmitting member placing step, the emission characteristic measurement step and the coating amount derivation processing step.
